(19) United States
(12) Patent Application Publication
(10) Pub. No.: US 2012/0056317 A1
(43) Pub. Date: Mar. 8, 2012

(54) CHIP

(75) Inventor: Meng-Che Yu, Tu-Cheng (TW)

(73) Assignee: HON HAI PRECISION INDUSTRY CO., LTD., Tu-Cheng (TW)

(21) Appl. No.: 12/878,966

(22) Filed: Sep. 9, 2010

(30) Foreign Application Priority Data
Sep. 2, 2010 (TW) 99129636

(51) Int. Cl. H01L 23/498

(52) U.S. Cl. 257/737; 257/E23.068

(57) ABSTRACT

A chip includes a body, a number of pins, and conductive pieces. The body includes a top surface and a bottom surface. The pins are arranged on the bottom surface. The conductive pieces are arranged on the top surface. The number of the conductive pieces equals to the number of the pins. Each pin is electrically connected to one conductive piece.

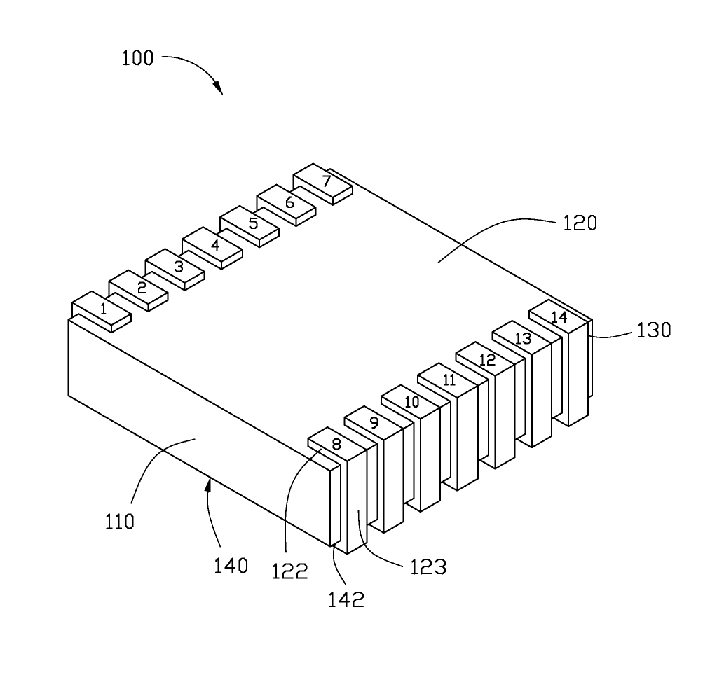

### BACKGROUND

1. Technical Field

The present disclosure relates to a chip.

2. Description of Related Art

Nowadays, surface mounted technology (SMT) is widely used to manufacture printed circuit boards (PCBs). Correspondingly, chips are designed as surface mounted devices (SMD), namely pins of a chip are surface mounted on a PCB. When a chip is sealed on a PCB, the pins of the chip are positioned under the chip, thus it is very hard to test the pins with a tester probe.

### BRIEF DESCRIPTION OF THE DRAWING

Many aspects of the present embodiments can be better understood with reference to the following drawing. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

The figure is a schematic, isometric view of an embodiment of a chip.

### DETAILED DESCRIPTION

The disclosure, including the accompanying drawing, is illustrated by way of example and not by way of limitation. It should be noted that references to “an” or “one” embodiment in this disclosure are not necessarily to the same embodiment, and such references mean at least one.

Referring to the figure, an embodiment of a chip 100 includes a body 110. The body 110 includes a top surface 120, a bottom surface 140 opposite to the top surface 120, and two opposite sidewalls 130 connected between corresponding sides of the top and bottom surfaces 120 and 140. A plurality of pins 142 are arranged on the bottom surface 140. The pins 142 are electrically connected to inner circuits (not shown) of the body 110.

These inner circuits fall within well-known technologies, and are therefore not described here. The number and positions of the pins 142 can be designed according to requirements, for example in the figure, the number of the pins 142 is fourteen and they are arranged in two parallel rows on the bottom surface 140.

A plurality of conductive pieces 122 is arranged on the top surface 120 of the body 110. The number of the conductive pieces 122 equals to the number of the pins 142. In one embodiment, the arrangement of the conductive pieces 122 on the top surface 120 is the same as the arrangement of the pins 142 on the bottom surface 140. Each pin 142 is electrically connected to a corresponding conductive piece 122 through a conductive board 123 arranged on the corresponding sidewall 130 of the body 110. The outside surfaces of the conductive boards 123 are coated with insulating material.

In one embodiment, each pin 142 with the corresponding conductive piece 122 and conductive board 123 can be integrally formed. Furthermore, the surfaces of the conductive pieces 122 can be marked, such as 1, 2, 3. . . 14, to distinctly distinguish the pins 122.

When the chip 100 is sealed on a printed circuit board (PCB) by surface mounted technology (SMT), the conductive pieces 122 are exposed to be easily contacted by a tester probe. In other words, the pins 140 can be easily tested by the tester through the conductive pieces 122. Additionally, the conductive pieces 122 mounted on the top surface 120 of the chip 100 can increase the heat dissipation area of the pins 142, thereby increasing heat dissipation.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A chip comprising:
a body comprising a top surface, and a bottom surface opposite to the top surface;
a plurality of pins arranged on the bottom surface; and
a plurality of conductive pieces arranged on the top surface, wherein the number of the plurality of conductive pieces equals to the number of the plurality of pins, each of the plurality of pins is electrically connected to one of the plurality of conductive pieces.

2. The chip of claim 1, further comprising a plurality of conductive boards, wherein the body further comprises sidewalls connected between the top and bottom surfaces, the plurality of conductive boards is arranged on corresponding sidewalls of the body, each of the plurality of conductive boards is electrically connected between one of the plurality of pins and the corresponding one of the plurality of conductive pieces.

3. The chip of claim 2, wherein outer surfaces of the conductive boards are coated with insulating material.

4. The chip of claim 2, wherein each of the plurality of pins with the corresponding one of the plurality of conductive pieces and the corresponding one of the plurality of conductive boards are integrally formed.

5. The chip of claim 1, wherein an arrangement of the plurality of conductive pieces on the top surface is the same as an arrangement of the plurality of pins.

6. The chip of claim 1, wherein a surface of each of the plurality of conductive pieces are marked.
